(19) United States
(12) Patent Application Publication
(10) Pub. No.: US 2026/0293037 A1
(43) Pub. Date: Sep. 24, 2026

(54) REDUNDANT AIRFLOW CIRCUIT FAN PODS FOR SERVER ELECTRONICS COOLING

(71) Applicant: International Business Machines Corporation, Armonk, NY (US)

(72) Inventors: William James ANDERL, Rochester, MN (US); Stephen P. MROZ, Rochester, MN (US); Justin Christopher ROGERS, Rochester, MN (US); Mert KARAKAS, Rochester, MN (US)

(21) Appl. No.: 18/958,423

(22) Filed: Nov. 25, 2024

(51) Int. Cl. H05K 7/20

(52) U.S. Cl. CPC H05K 7/20145

(57) ABSTRACT

Methods and apparatus are provided for facilitating cooling of an electronic device. The apparatus includes a first fan pod, a second fan pod, and the electronic device. The first fan pod includes a first fan, which is configured to pull air from an external environment into a chassis, and a first anti-recirculation flapper, which is positioned adjacent to the first fan within the first fan pod. The second fan pod includes a second fan, which is configured to exhaust air within the chassis to the external environment, and a second anti-recirculation flapper, which is positioned adjacent to the second fan within the second fan pod. The electronic device is positioned between the first fan pod and the second fan pod, where airflow generated by the first pan pod passes the electronic device before being exhausted by the second fan pod.

### BACKGROUND

The present disclosure relates to airflow management, and more specifically, to the use of redundant airflow circuit fan pods for controlling airflow and facilitating the cooling of electronic devices.

### SUMMARY

One embodiment presented in this disclosure provides an apparatus for cooling an electronic device, including a first fan pod, a second fan pod, and the electronic device. The first fan pod includes a first fan, which is configured to pull air from an external environment into a chassis, and a first anti-recirculation flapper, which is positioned adjacent to the first fan within the first fan pod. The second fan pod includes a second fan, which is configured to exhaust air within the chassis to the external environment, and a second anti-recirculation flapper, which is positioned adjacent to the second fan within the second fan pod. The electronic device is positioned between the first fan pod and the second fan pod, where airflow generated by the first fan pod passes the electronic device before being exhausted by the second fan pod.

One embodiment presented in this disclosure provides an apparatus for cooling an electronic device, including a fan pod and the electronic device. The fan pod includes a fan, which is configured to direct air between an external environment and a chassis, and an anti-recirculation flapper, which is positioned adjacent to the fan and configured to control the direction of airflow generated by the fan. The electronic device is within the chassis, where the airflow generated by the fan passes the electronic device to facilitate cooling.

One embodiment presented in this disclosure provides a method for cooling an electronic device, including generating an airflow by operating a first fan pod positioned at the front of the electronic device, where the first fan pod includes a first fan and a first anti-recirculation flapper adjacent to the first fan, and where generating the airflow includes that the first fan pulls air from an external environment into a chassis, directing the airflow to pass the electronic device to facilitate cooling, exhausting the airflow from the chassis by operating a second fan pod positioned at the rear of the electronic device, where the second fan pod includes a second fan and a second anti-recirculation flapper adjacent to the second fan, and where exhausting the airflow comprises that the second fan expels air from the chassis to the external environment, and in response to normal operation of the first and second fans, controlling the first anti-recirculation flapper in the first fan pod to prevent air from flowing back from the chassis to the external environment, and controlling the second anti-recirculation flapper in the second fan pod to prevent air from flowing from the external environment into the chassis.

### BRIEF DESCRIPTION OF THE DRAWINGS

FIG. 1A shows an example push-pull cooling system with redundant fan pods, where both front and rear fans operate normally, according to some embodiments of the present disclosure.

FIG. 1B shows an example push-pull cooling system with redundant fan pods, where a front fan fails, according to some embodiments of the present disclosure.

FIG. 1C shows an example push-pull cooling system with redundant fan pods, where a rear fan fails, according to some embodiments of the present disclosure.

FIG. 2A shows a front view of an equipment chassis with a multi-domain cooling system, according to some embodiments of the present disclosure.

FIG. 2B shows a side view of an equipment chassis with a multi-domain cooling system, according to some embodiments of the present disclosure.

FIG. 3A shows a front view of a storage airflow domain, according to some embodiments of the present disclosure.

FIG. 3B shows a top view of a storage cooling domain, where front and rear fans operate normally, according to some embodiments of the present disclosure.

FIG. 3C shows a top view of a storage cooling domain, where a front fan fails, according to some embodiments of the present disclosure.

FIG. 3D shows a top view of a storage cooling domain, where a front fan fails and a front fan pod is pulled out for replacement, according to some embodiments of the present disclosure.

FIG. 3E shows a top view of a storage cooling domain, where a rear fan fails, according to some embodiments of the present disclosure.

FIG. 3F shows a top view of a storage cooling domain, where a rear fan fails and a rear fan pod is pulled out for replacement, according to some embodiments of the present disclosure.

FIG. 4 shows a bar graph illustrating airflow under different operating conditions, according to some embodiments of the present disclosure.

FIG. 5 depicts an example method for managing airflow in a push-pull cooling system with anti-recirculation features, according to some embodiments of the present disclosure.

FIG. 6 is a flow diagram depicting an example method for facilitating cooling of an electronic device within a chassis, according to some embodiments of the present disclosure.

FIG. 7 depicts an example control unit configured to perform various aspects of the present disclosure, according to some embodiments of the present disclosure.

### DETAILED DESCRIPTION

Electronic devices, such as servers, data storage units, and network devices, are typically enclosed within a chassis or other types of enclosures. These devices can generate considerable heat during operation, which requires effective cooling to avoid overheating and maintain optimal performance. Cooling within the chassis is commonly achieved through the use of one or more fans within the chassis, which provide continuous airflow that pulls cooler air into the chassis and exhausts warm air out.

However, when one of the cooling fans fails, the overall airflow within the chassis can be significantly reduced. This is because, even when the fan stops operating, air still needs to pass through the fan's assembly, as there is often no alternative path for the airflow. The stationary blades and other components of the fan create an obstruction, forcing the air to squeeze through the small gaps between the blades. Such restricted passage significantly reduces the overall airflow, further increasing the risk of overheating or thermal throttling of the electronic device, as the heat generated by the device cannot be dissipated effectively.

As the demand for more advanced computing capabilities grows, particularly in areas like artificial intelligence (AI) calculations and data processing, electronic devices are generating even more heat. The increase in heat poses greater challenges for cooling system within enclosure. Higher airflow rates are needed to cool high-power modules and to limit the temperature of the air that is exhausted from the chassis to the surrounding environment. One approach to managing the increased heat load is to boost fan power or utilize multiple fans to increase airflow. However, increasing fan power or adding more fans requires additional space, increases noise levels, and leads to higher costs. Additionally, this approach increases the risk of fan failure, as more components are involved. When a fan does fail, as discussed above, the airflow rate drops significantly due to the obstruction caused by the non-operational fan blades. Following that, the risk of overheating rises rapidly, further intensifying the already significant thermal challenges in high-power systems.

The present disclosure provides methods and apparatus for managing airflow within a chassis that encloses electronic devices and preventing the significant airflow drops that occur during fan failure. One embodiment of the present introduces a redundant airflow circuit fan pod (hereinafter referred to as “redundant fan pod” or “fan pod”). The redundant fan pod includes a fan and an anti-recirculation flapper (also referred to in some embodiments as non-return damper or anti-recirculation damper). The redundant fan pod may be positioned anywhere in or on the devices or chassis, including, but not limited to, the front, rear, top, bottom, or sides, depending on the specific cooling requirements of the system.

In one embodiment, two redundant fan pods may be positioned at the front (or upstream) and rear (or downstream) of the electronic devices (e.g., one near the air inlet and the other near the air outlet) to maintain efficient cooling and prevent airflow reduction during fan failure. The anti-recirculation flappers within these fan pods may dynamically adjust in response to the operational status of the fans. During normal operation, the flappers in both pods may remain closed to prevent backflow and obstruction. When a fan fails, such as the fan in the front (or upstream) pod, the flapper in the front (or upstream) pod may open to allow air to bypass the non-operational fan, facilitating airflow and maintaining continuous cooling. Similarly, if the fan in the rear (or downstream) pod fails, the rear (or downstream) flapper may open, allowing the airflow to continue through an alternative path, bypassing the non-operational fan. Even if one fan pod is removed for fan replacement, airflow may continue through the chassis (e.g., through the hole left by removal of the failed fan), which minimizes (or at least reduces) disruptions to the cooling process and prevents overheating.

Embodiments of the present disclosure introduce an effective cooling mechanism for high-performance electronic systems, which require more efficient thermal management due to the substantial heat generated during operation. Instead of relying on complex multi-fan configurations, such as a 2×2 push-pull setup, to handle the cooling demands, the present disclosure introduces the use of redundant fan pods within the chassis. By dynamically adjusting the anti-recirculation flapper, the fan pod avoids the significant airflow drop typically caused by stationary fan blades obstructing airflow during fan failure. This approach preserves cooling efficiency both during normal operations and in the event of fan failure, without the need for complex multi-fan systems. Additionally, with fewer fan used, the cooling system in the present disclosure reduces overall power consumption, lowering operational costs while maintaining effective cooling. Furthermore, noise levels and wear-to-tear on components may also be reduced with fewer fans, leading to longer system life and improved sustainability.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.”

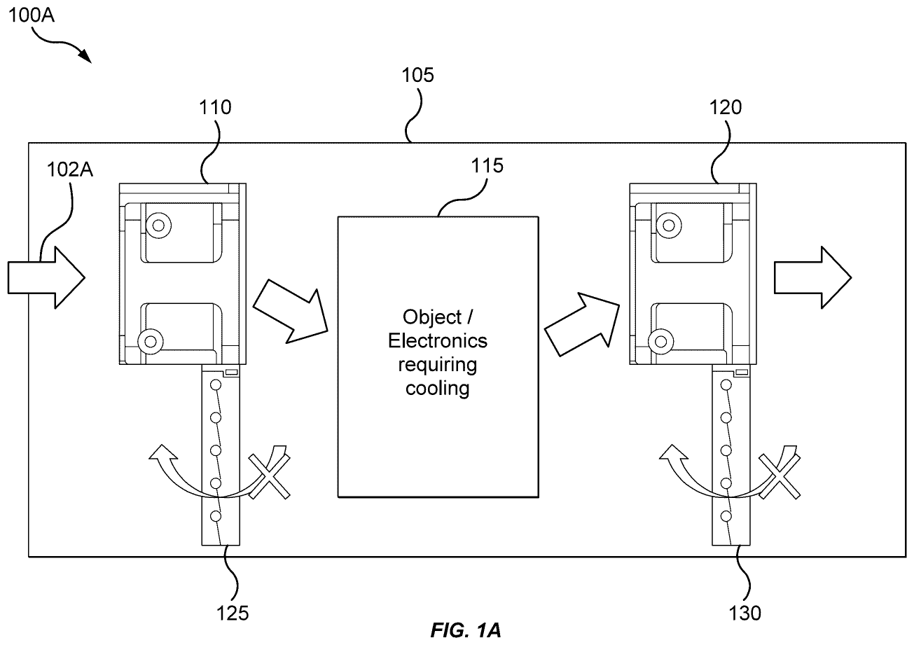

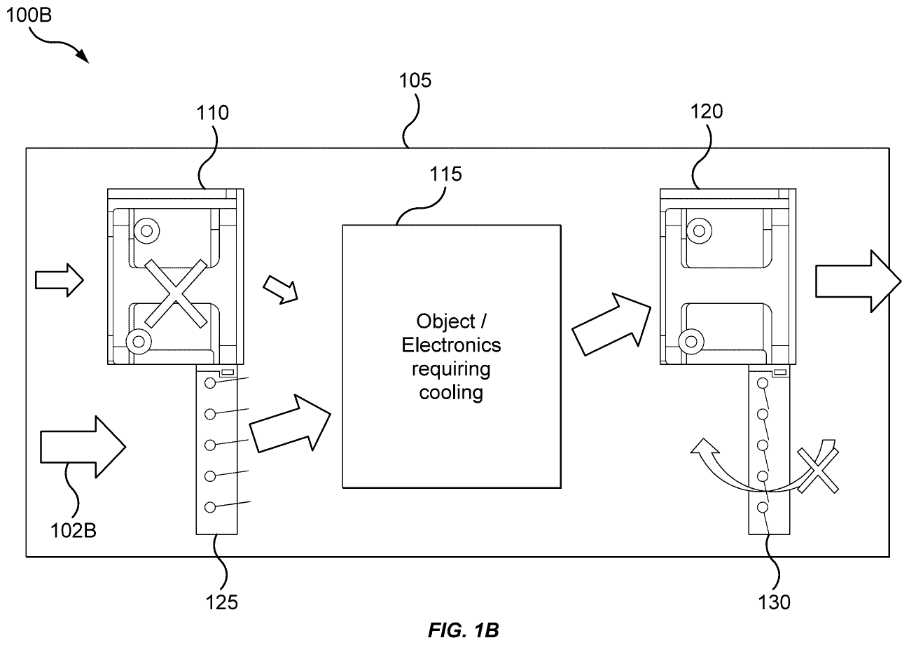

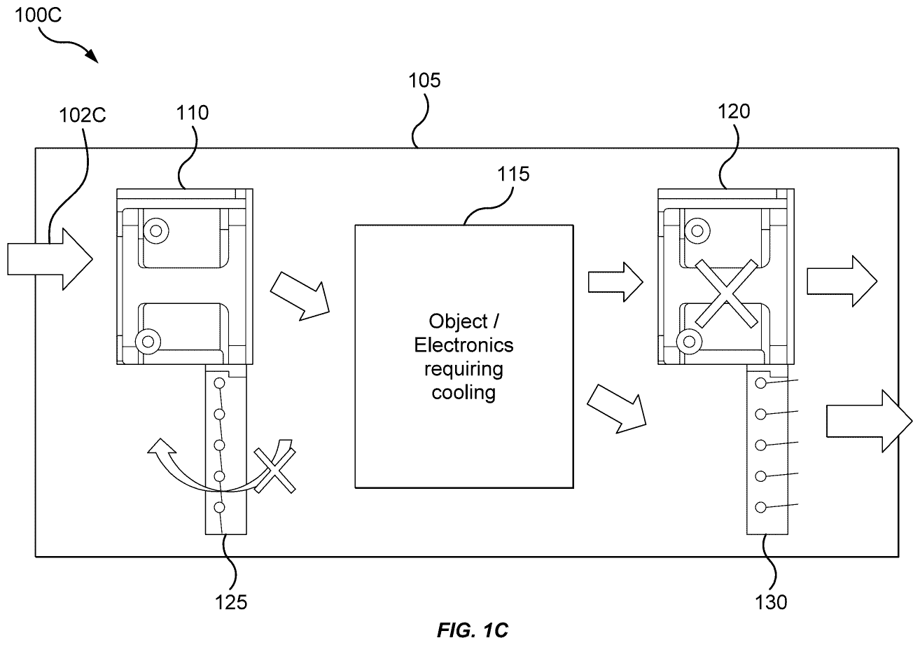

FIG. 1A shows an example push-pull cooling system 100A with redundant fan pods, where both front and rear fans 110 and 120 operate normally, according to some embodiments of the present disclosure.

As depicted, the push-pull cooling system 100A includes two redundant fan pods, one positioned at the front (or upstream) of the electronic components 115 requiring cooling, and one positioned at the rear (or downstream) of the electronic components 115. The redundant fan pods and the electronic components are enclosed within a chassis 105. The front fan pod (also referred to in some embodiments as the upstream fan pod) consists of a front fan 110 (also referred to in some embodiments as the upstream fan) and a front anti-recirculation flapper 125 (also referred to in some embodiments as anti-recirculation damper), where the flapper 125 is positioned below the fan 110. Similarly, the rear fan pod (also referred to in some embodiments as the downstream fan pod) includes a rear fan 120 (also referred to in some embodiments as the downstream fan) and a rear anti-recirculation flapper 130 (also referred to in some embodiments as the downstream anti-recirculation flapper), where the flapper 130 is positioned below the rear fan 120.

In this system 100A, as depicted, both fans 110 and 120 are operating normally. The front fan 110 draws cooler air from the external environment into the chassis 105. The air flows through the electronic components 115 (as depicted by the airflow arrow 102A), absorbing the heat generated during operation. The heated air is then exhausted by the rear fan 120 out of the chassis 105.

Each anti-recirculation flapper 125 or 130 consists of one or more hinged plates that pivot to a closed position when the corresponding fan is operating normally. As depicted, the front anti-recirculation flapper 125 is closed to prevent inside cool air from flowing back to the outside (via the front of the chassis 105), and the rear anti-recirculation flapper 130 remains closed to prevent outside air from flowing into the chassis from the rear. This configuration ensures that airflow is maintained in a single direction, from the front to the rear, without any backflow.

In some embodiments, the anti-recirculation flappers 125 and 130 remain closed naturally due to the air pressure created by the functioning fans 110 and 120. The difference in pressure between the chassis 105 and external environment may keep the flappers sealed, without the need for any additional control mechanism.

In some embodiments, the anti-recirculation flappers 125 and 130 and the fans 110 and 120 may be connected to a central control unit. The control unit may monitor the operational status of the fans 110 and 120, and actively keep the flappers 125 and 130 closed when it detects that the fans are working normally.

In some embodiments, in addition to, or instead of, relying on natural air pressure or active control to manage the anti-recirculation flappers 125 and 130 (keeping them open or closed), in some embodiments, the flappers may be passively controlled. The flapper may be biased to stay close using mechanisms such as spring pressure, which keeps the flapper closed and only opens when normal airflow fails. Alternatively, the flapper may be biased to stay open, with the pressure from normal fan operation holding it closed. In this configuration, the flapper may automatically open when the airflow stops, allowing air to bypass the failed fan and maintain proper cooling.

The example push-pull cooling system 100A is different from an existing or conventional cooling system in that it includes anti-recirculation flapper 125 and 130 installed below each fan in the front and rear fan pods. In a conventional cooling system, no such flappers are installed. Both systems work effectively when the fans operate normally, maintaining airflow and cooling efficiency. However, when one fan fails (whether the front or rear fan), the airflow in the conventional system drops significantly. This is because, in the conventional system, there is no alternative path for airflow, forcing the air to squeeze through the small gaps between the stationary blades, which severely reduces airflow rate and cooling efficiency. In contrast, the example cooing system 100A provides an alternative path for airflow by opening the anti-recirculation flappers 125 and 130 when a fan fails. More details about this improvement are discussed below with references to FIGS. 1B and 1C.

FIG. 1B shows an example push-pull cooling system 100B with redundant fan pods, where a front fan 110 fails, according to some embodiments of the present disclosure.

As depicted, the front fan 110 has failed and stopped working, and the front anti-recirculation flapper 125 opens (with hinged plates pivot to an open position). The open flapper 125 allows air to bypass the non-functional fan 110 and therefore avoid significant airflow reduction (as depicted by the airflow arrow 102B). As a result, the rear fan 120 continues to pull air through the chassis 105 (via the flapper 125) and over the electronic components 115, maintaining cooling efficiency despite the front fan's failure. As depicted, the rear anti-recirculation flapper 130 remains closed (with hinged plates pivoted to a closed position), preventing air from flowing back into the chassis 105 from the rear.

In some embodiments, the opening of the front flapper 125 and the closing of the rear flapper 130 occur naturally due to the pressure difference between the inside and outside of the chassis, with no need for additional control.

In some embodiments, the flappers 125 and 130 and the fans 110 and 120 may be connected to a central control unit. The central control unit may monitor the operational status of the fans. Upon detecting the front fan's failure, the control unit may open the front flapper 125 and keep the rear flapper 130 closed.

FIG. 1C shows an example push-pull cooling system 100C with redundant fan pods, where a rear fan 120 fails, according to some embodiments of the present disclosure.

As depicted, the rear fan 120 has failed and stopped working, and the rear anti-recirculation flapper 130 opens (with hinged plates pivoted to an open position). The open flapper 130 allows the air to bypass the non-functional rear fan 120 and be exhausted from the chassis 105 (as depicted by the airflow arrow 102C). Despite the rear fan's failure, the front fan 110 continues to operate normally, pulling cool air into the chassis 105 and maintaining airflow through the electronic components 115. With the rear flapper 130 open, the system 100C may avoid a significant drop in airflow rate, effectively exhausting heated air and maintaining cooling efficiency.

In some embodiments, the opening of the rear flapper 130 and the closing of the front flapper 125 may occur naturally due to pressure differences. In some embodiments, a central control unit may be used to manage the opening and closing of flappers. The control unit may detect the rear fan failure and, based on the detection, open the rear flapper to maintain proper airflow. In some embodiments, the flappers may be passively controlled using mechanisms such as spring pressure, where the flappers are biased to stay closed during normal fan operation and automatically open when airflow drops due to fan failure.

As discussed above, compared with a conventional/existing cooling system, the example cooling system has the anti-recirculation flapper 125 and 130 installed below each fan. These flappers provide an alternative airflow path when a fan fails, maintaining cooling efficiency within the chassis. In a conventional push-pull cooling system, when a fan fails (either the front fan or the rear fan), the airflow is significantly reduced. Without an anti-recirculation flapper, the air is forced to squeeze through the stationary blades of the non-functional fan. This restriction causes a substantial drop in airflow rate, leading to insufficient cooling. As a result, the electronic components within the chassis may overheat, causing performance degradation, potential thermal throttling, or even hardware failure.

In contrast, the example push-pull cooling system 100A-C addresses these issues by opening the anti-recirculation flappers 125 and 130 when either the front or rear fan fails. If the front fan 110 fails, the front anti-recirculation flapper 125 opens, allowing air to bypass the stationary front fan and continue flowing through the electronic components 115. If the rear fan 120 fails, the rear anti-recirculation flapper 130 opens, allowing the front fan 120 to push air through the electronic components 115 and exhaust the heated air out of the chassis. The design of the example cooling system prevents the significant airflow drop and overheating problems observed in conventional systems and provides more reliable and efficient cooling during fan failure.

The two redundant fan pods as depicted in FIGS. 1A-1C, each including a single fan and an anti-recirculation flapper, are provided for conceptual clarity. In some embodiments, the redundant fan pod may include more than one fan. These fans may be organized side by side or in a stacked configuration within the pod to increase airflow capacity. The anti-recirculation flapper may be positioned below, above, besides, or in any other suitable location relative to the fan within the pod. When one or more fans fail, the flapper opens to create an alternative pathway for the airflow, bypassing the non-functional fan and maintaining cooling efficiency. In some embodiments, the flapper and the fan(s) may be components of a single/integrated unit. This integration allows for simplified installation and replacement, as the entire assembly may be handled as one unified component.

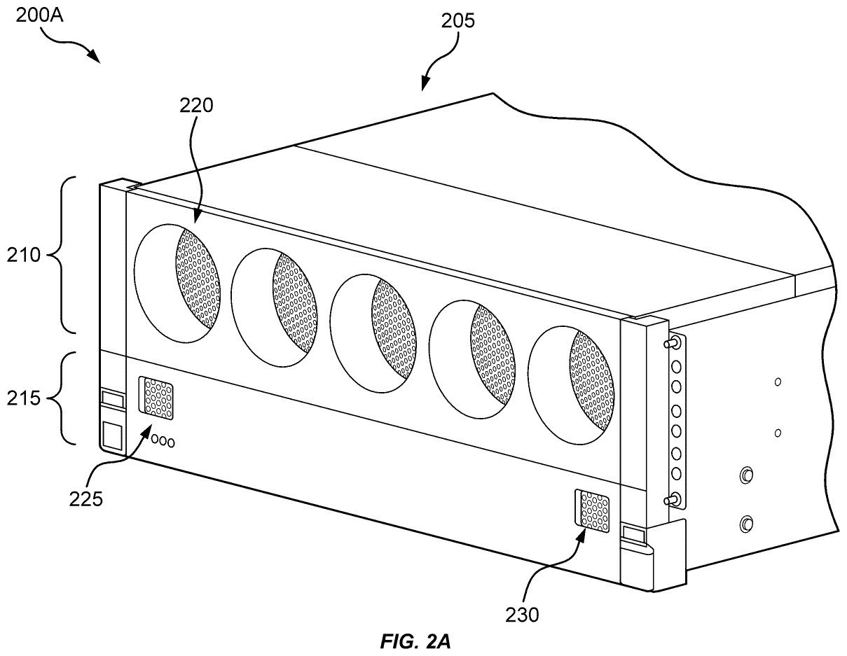

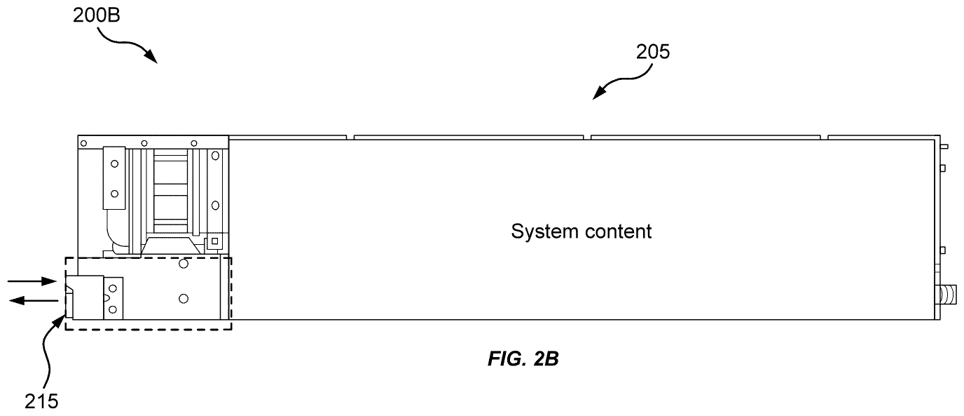

FIG. 2A shows a front view 200A of an equipment chassis 205 with a multi-domain cooling system, according to some embodiments of the present disclosure.

As depicted, the equipment chassis 205 includes two separate airflow domains: the upper part is the main system airflow domain 210, and the lower part is the storage airflow domain 215. In the main system airflow domain 210, as depicted, there are five air inlets 220 (also referred to in some embodiments as inlet vents). In some embodiments, the main system airflow domain 210 may include five fans (e.g., 80 mm fans) positioned next to these inlets 220, pulling air from outside the main system airflow domain, circulating it through the main system to cool the electronics, and then pushing the warm air out of the domain at the rear side. In some embodiments, the server fans may also be referred to as CEC fans, ancillary fans, server-level fans, rack-level fans, or drawer-level fans.

The storage airflow domain 215, as illustrated, includes both an air inlet 225 (also referred to in some embodiments as an inlet vent) and an air outlet 230 (also referred to in some embodiments as an exhaust vent). In some embodiments, the storage airflow domain 215 may include a redundant fan pod (as depicted in FIGS. 2A-2C) located in or near the inlet 225, and another redundant fan pod placed in or near the outlet 230. Each fan pod includes a fan (e.g., 110 or 120 of FIG. 1A) and an anti-recirculation flapper (e.g., 125 or 130 of FIG. 1A). During normal operation, the front fan (e.g., 110 of FIG. 1A) in the front fan pod pulls air from outside into the storage airflow domain, passes the air over the storage media, and the rear fan (e.g., 120 of FIG. 1A) in the rear fan pod exhausts the air through the outlet 230 to outside. The anti-recirculation flappers remain closed during normal operation to maintain airflow direction. When a fan fails, the corresponding flapper may open to direct air bypass the non-functional fan.

In some embodiments, the server fans may help to prevent recirculation within the storage fan pod located in the lower storage airflow domain 215. By drawing fresh air into the inlets 220 at the top, the server fans create airflow patterns that draw fresh air to enter the storage airflow domain 215 through the inlet 225. As depicted, the inlets 220 are placed above the inlet 225, and therefore a portion of the air drawn into the main system may also flow into the fan near the inlet 225, assisting with storage cooling. Additionally, because the outlet 230 is located below the inlets 220, the server fans may draw the preheated exhaust air back toward the main system airflow domain 210, preventing the preheated air from recirculating into the storage fan pod.

In some embodiments, the storage airflow domain 215 may include only one redundant fan pod, such as when the pod with a failed fan has been removed from the domain for fan replacement. The system continues to provide cooling even with only one fan pod. For example, if the front fan pod is removed, the rear fan continues to pull air from the inlet 225 without obstruction, and therefore maintain airflow and cooling efficiency. Similarly, if the rear fan pod is removed, the front fan may continue to push air through the storage domain and exhaust warm air to outside via the outlet 230 without obstruction.

FIG. 2B shows a side view 200B of an equipment chassis 205 with a multi-domain cooling system, according to some embodiments of the present disclosure. This figure illustrates the fully sealed separation between the storage airflow domain 210 and the main system airflow domain 215. As shown, the storage airflow domain 215 is completely isolated from the system airflow domain. This configuration provides that each domain has its own dedicated cooling system.

The sealed separation maximizes (or at least improves) the cooling efficiency for both areas. By isolating the storage airflow domain, airflow from the main system (which is typically handled by larger system fans, like 80 mm fans) focuses entirely on cooling central electronic components (CECs) without being diverted to cool storage media. This setup optimizes the performance of the system fans, allowing them to maximize (or at least improve) cooling for high-power components. Additionally, the dedicated cooling system for the storage domain allows the storage media to receive adequate cooling without affecting or reducing the airflow available for the main system.

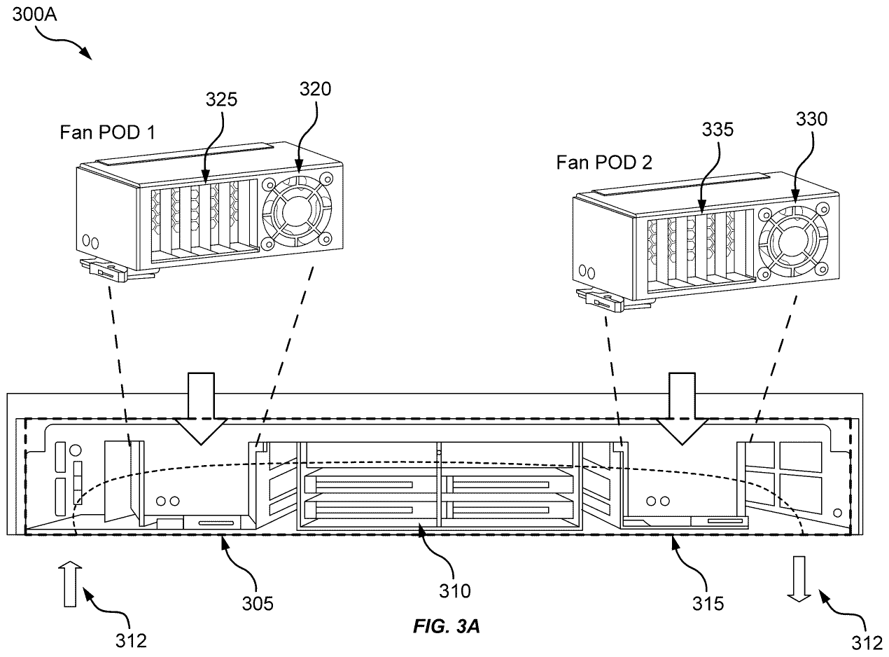

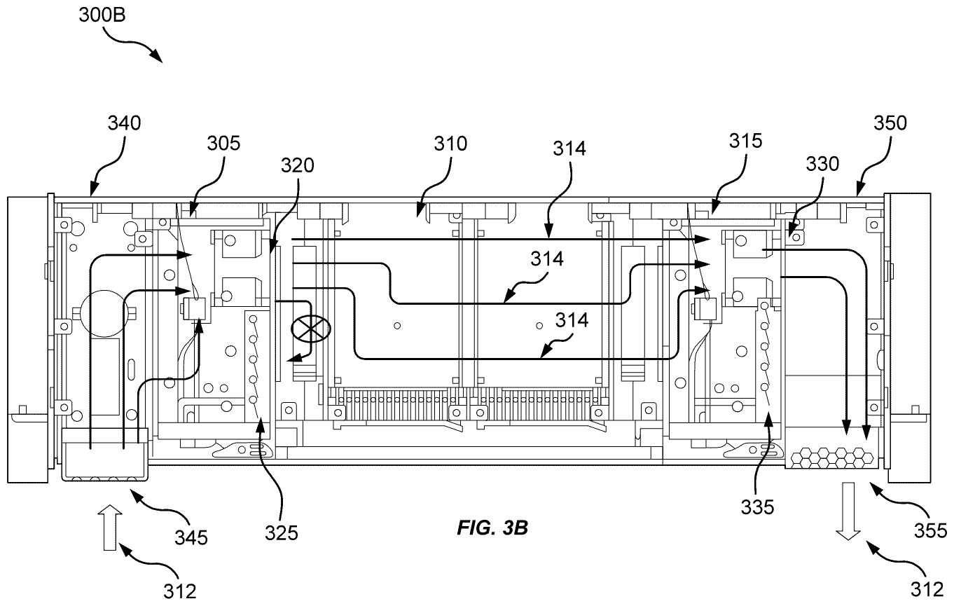

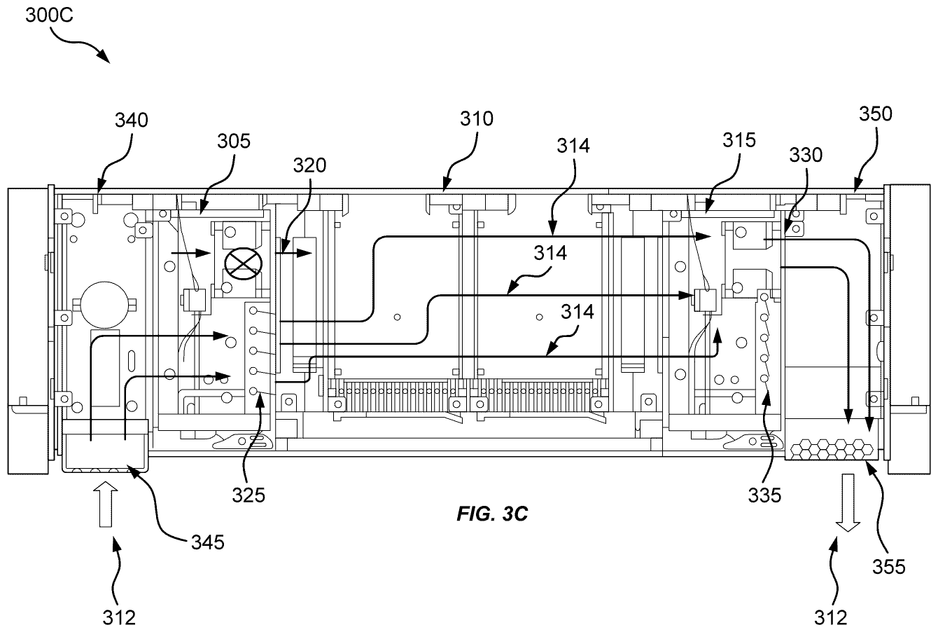

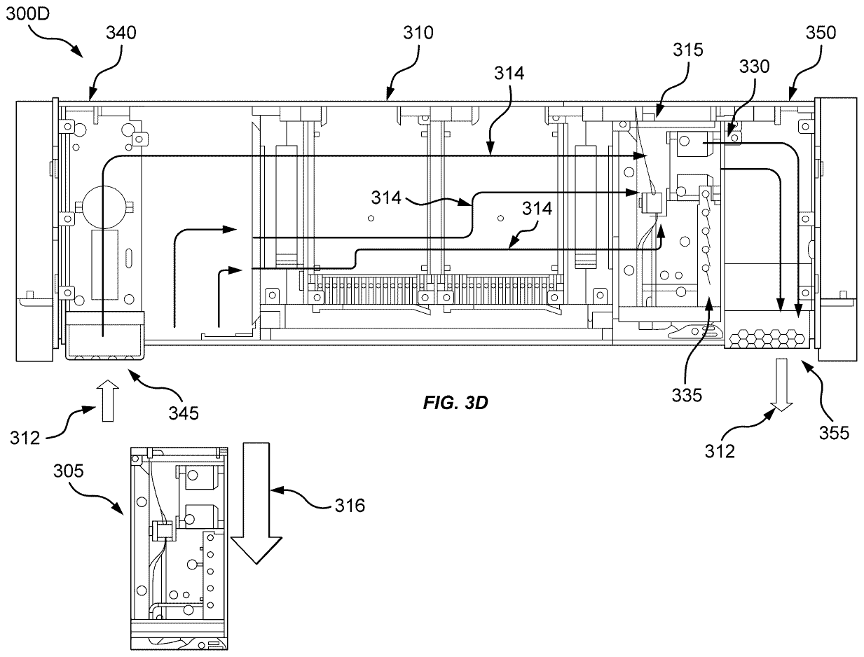

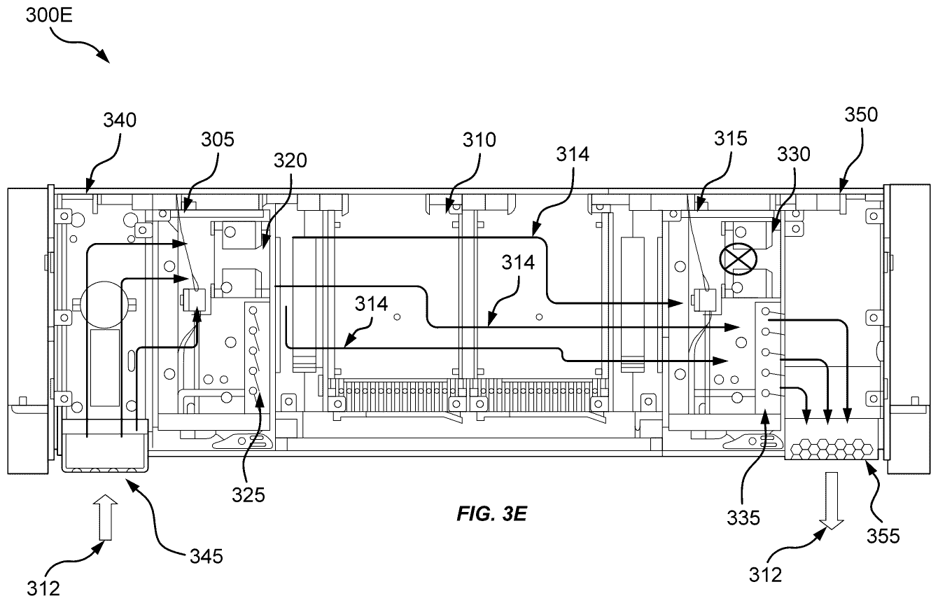

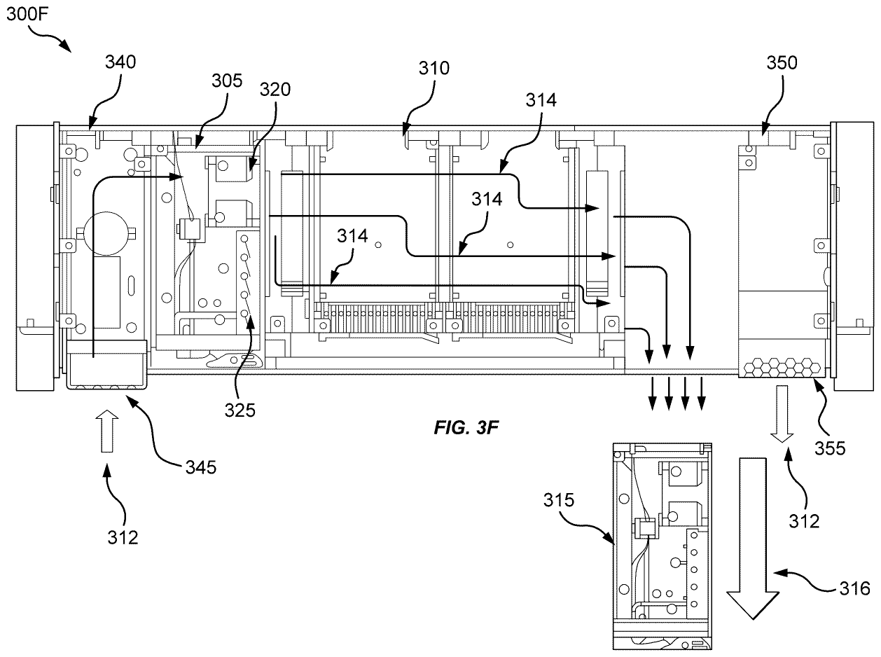

FIG. 3A shows a front view 300A of a storage airflow domain, according to some embodiments of the present disclosure. The storage airflow domain in this figure may correspond to the storage airflow domain 215 as depicted in FIGS. 2A-2B.

As illustrated, the storage airflow domain includes a front redundant fan pod 305 near the air inlet, a rear redundant fan pod 315 near the air outlet, and one or more storage disks or media 310 that require cooling. The one or more storage disks or media 310 are positioned between the two redundant fan pods 305 and 315. As depicted, the front fan pod 305 includes a front fan 320 and an anti-recirculation flapper 325. The rear fan pod 315 includes a rear fan 330 and an anti-recirculation flapper 335. During normal operations, air is pulled into the domain by the front fan 320, passes over the storage media 310, and is then exhausted by the rear fan 330 to the outside (as depicted by the airflow arrow 312).

FIG. 3B shows a top view 300B of a storage cooling domain, where front and rear fans operate normally, according to some embodiments of the present disclosure. The storage airflow domain in this figure may correspond to the storage airflow domain 215 as depicted in FIGS. 2A-2B.

As illustrated, the front fan pod 305 is positioned adjacent to a chamber or duct 340 that directs airflow from the inlet 345 into the front fan 320. The chamber or duct 340 includes a channel that features an approximate 90-degree or obtuse angle (which may include angles like 100 or 120 degrees), allowing the incoming air to make an approximate 90-degree turn before entering the front fan 320.

As depicted, the airflow is pulled vertically through the inlet 345 into the chamber 340 (as depicted by the airflow arrow 312), where it turns around 90 degrees, becoming horizontal, before being directed into the front fan 320. Similarly, on the exhausted side of the system, a corresponding chamber or duct 350 is positioned next to the rear fan pod 315. Once the air passes over the storage media 310 and is pulled into the rear fan 330, the chamber 350 directs the air to make an approximate 90-degree turn before being expelled through the outlet 355 (as depicted by the airflow arrow 312). The design of the chamber can reduce turbulence and lower noise and enhance the overall performance of the cooling system. The airflow paths within the chamber 340 are depicted by the curved solid-line arrow 314.

As depicted, both the front and rear fans 320 and 330 are operating normally, and the anti-recirculation flappers 325 and 335 in both the front and rear fan pods remain closed. As discussed above, the closing of the flapper may occur naturally due to the pressure difference between the inside and outside of the domain. In some embodiments, the flapper may be managed by a control unit that monitors the operational status of the fans. The control unit may keep the flappers closed when both fans are functioning properly and dynamically adjusting them if a fan failure is detected.

FIG. 3C shows a top view 300C of a storage cooling domain, where a front fan 320 fails, according to some embodiments of the present disclosure. The storage airflow domain in this figure may correspond to the storage airflow domain 215 as depicted in FIGS. 2A-2B.

As depicted, the front fan 320 has failed and stopped working, and the anti-recirculation flapper 325 in the front fan pod 305 opens, allowing air to bypass the non-functional fan and enter the storage airflow domain. As illustrated, air is drawn in through the inlet 345 (as depicted by the airflow arrow 312). The chamber 340 next to the front fan pod 305 directs the airflow, turning an approximate 90-degree turn before entering the front fan 320. The air then passes through the storage media, absorbs heat, and continues to the rear fan pod 315. In the rear fan pod 315, the heated air is pulled into the fan 330, and the chamber 350 next to the rear fan pod 315 redirects the airflow, making another approximate 90-degree turn before being expelled through the outlet 355 (as depicted by the airflow arrow 312). Despite the failure of the front fan 320, the airflow is maintained throughout the system, allowing the storage components 310 to remain cool and preventing overheating. The airflow paths within the chamber 340 are depicted by the curved solid-line arrow 314.

In some embodiments, as discussed above, the opening of the front flapper 325 and/or the closing of the rear flapper 335 may occur naturally due to pressure differences within the system. In some embodiments, the flappers 325 and 335 may be actively controlled by a central control unit. The control unit may monitor the operational status of the fans 320 and 330 and adjust the flapper positions dynamically, such as opening the front flapper when the front fan fails and keeping the rear flapper closed to prevent backflow.

FIG. 3D shows a top view of a storage cooling domain, where a front fan 320 fails and a front fan pod 305 is removed for replacement, according to some embodiments of the present disclosure. The storage airflow domain in this figure may correspond to the storage airflow domain 215 as depicted in FIGS. 2A-2B.

As depicted, the front fan pod 305 is removed from the storage airflow domain for fan replacement (as depicted by the removal arrow 316). With the front fan pod 305 removed, as depicted, air still enters the domain through the inlet 345 (as depicted by the airflow arrow 312). Since the rear fan 330 is operating normally, the rear fan 330 effectively maintains negative pressure within the domain, pulling the incoming air through the storage media or electronics 310 to take away the heat generated by these components. After passing through the storage media, the air is exhausted through the outlet 355 by the rear fan 330 (as depicted by the airflow arrow 312). The airflow paths within the chamber 340 are depicted by the curved solid-line arrow 314.

The setup within the storage airflow domain, as depicted in this figure, allows that cooling continues uninterrupted, even when the front fan pod 305 is removed from maintenance or replacement. Traditionally, the time allowed for fan replacement is very short (or limited), as removing a fan can cause a significant drop in airflow rate, leading to an increased risk of overheating. However, in this setup, the time for fan replacement may be more flexible, since the rear fan maintains airflow throughout the domain, and the system continues to cool effectively even with one fan pod removed.

FIG. 3E shows a top view of a storage cooling domain, where a rear fan 330 fails, according to some embodiments of the present disclosure. The storage airflow domain in this figure may correspond to the storage airflow domain 215 as depicted in FIGS. 2A-2B.

As depicted, the rear fan 330 has failed, and the rear anti-recirculation flapper 335 has opened to allow heated air to exhaust through the outlet 355. As shown, air is pulled by the front fan 320 through the inlet 345 (as depicted by the airflow arrow 312). The front fan pod 305 is positioned next to the chamber 340, which directs the airflow to make an approximate 90-degree turn and enter the domain. The air then passes through the storage media or electronics 310 and absorbs heat generated by these components. The front anti-recirculation flapper 325 remains closed to prevent backflow from the domain to the external environment.

As depicted, after passing through the electronic components, the heated air is exhausted through the opening of the rear anti-recirculation flapper 335, bypassing the non-functional rear fan 330. Since there is no obstruction caused by the stationary rear fan 330, the airflow rate does not drop. The heated air is then redirected by the chamber 350 next to the rear fan pod 315, turning 90 degrees before existing through the outlet 355 (as depicted by the airflow arrow 312). This setup maintains consistent airflow, even when the rear fan has failed. The airflow paths within the chamber 340 are depicted by the curved solid-line arrow 314.

In some embodiments, the opening and closing of these flappers (e.g., the closing of the front flapper 325 and the closing of the rear flapper 335) may occur naturally due to pressure differences between the inside and outside of the domain. In some embodiments, these flappers 325 and 335 and fans 320 and 330 may be controlled by a central unit, which monitors each fan's status and dynamically adjusts the flappers to maintain consistent airflow.

FIG. 3F shows a top view of a storage cooling domain, where a rear fan 330 fails and a rear fan pod 315 is pulled out for replacement, according to some embodiments of the present disclosure.

As depicted, the rear fan 330 failed, and the rear fan pod 315 is pulled out from the storage airflow domain for replacement. The front fan 320 continues to operate normally, pulling cool air from outside through the inlet 345 (as depicted by the airflow arrow 312) and pushing it over the electronic components 310. As the air passes through the electronics 310, the air absorbs heat, and the front fan 320 pushes the heated air toward the outlet 355 (as depicted by the airflow arrow 312). Even though the rear fan pod 315 is removed (as depicted by the removal arrow 316), the system maintains continuous cooling without interruptions. As such, fan pod replacement may be done without urgency. This configuration allows more flexibility in maintenance schedules without compromising the cooling performance of the system. The airflow paths within the chamber 340 are depicted by the curved solid-line arrow 314.

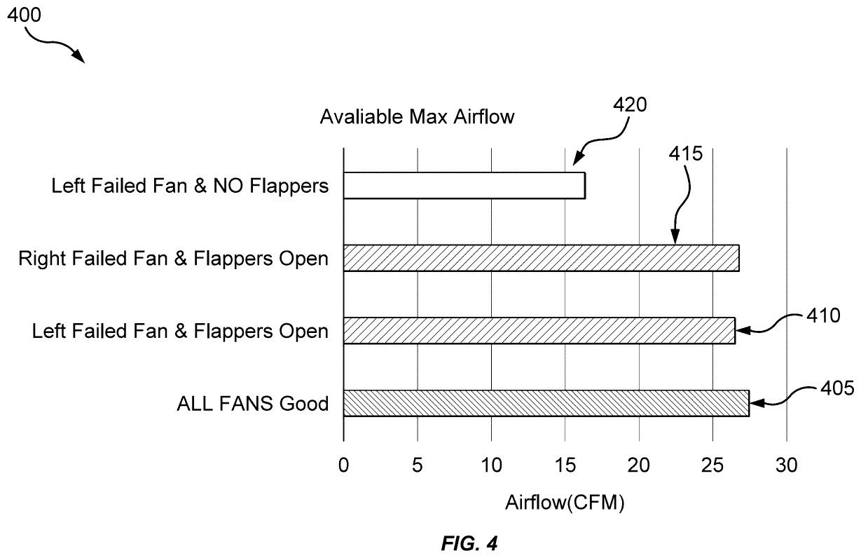

FIG. 4 shows a bar graph 400 illustrating airflow under different operating conditions, according to some embodiments of the present disclosure. The graph 400 illustrates the airflow rates (measured in CFM (cubic feet per minute)) under different fan operation scenarios, such as when both fans are functional, when one fan fails and the flapper opens, and when no flapper opens.

As depicted, bar 405 represents the scenario where both the front fan (e.g., 320 of FIG. 3A) and rear fan (e.g., 330 of FIG. 3A) are working normally. In this scenario, the airflow rate is 27.5 CFM. Bar 410 represents the scenario where the front fan (left fan) (e.g., 320 of FIG. 3C) fails, with the flapper (e.g., 325 of FIG. 3C) in the front fan pod open to maintain airflow. In this scenario, the airflow rate is 27 CFM, indicating that the system continues to function effectively despite the failure, with only a slight reduction in airflow rate.

Bar 415 depicts the situation where the rear fan (right fan) (e.g., 330 of FIG. 3E) fails, with the flapper (e.g., 335 of FIG. 3E) in the rear fan pod open. The airflow in this situation is maintained at 27.5 CFM, indicating there is no noticeable drop in airflow rate when the rear fan fails. Bar 420 shows the existing push-pull cooling system where the front fan (left fan) fails, but no flapper opens to maintain airflow (so that air is squeezed into the small gaps between the stationary fan blades). In this scenario, the airflow drops significantly to 16 CFM, which is approximately 60% of the normal operation airflow rate of 27.5 CFM. The percentage drop in airflow when the front fan fails in the existing push-pull cooling system may be calculated as follows:

$$Percentage Drop = [ ( 27.5 - 16 ) / 27.5 ] \times 100 = 41 \text{.82} \%$$

Therefore, the absence of a flapper in the existing system results in a 41.82% reduction in airflow when the front fan fails. This bar graph 400 highlights the importance of the redundant fan pod and its anti-recirculation flapper mechanism in maintaining efficient cooling and preventing significant airflow reduction when a fan fails.

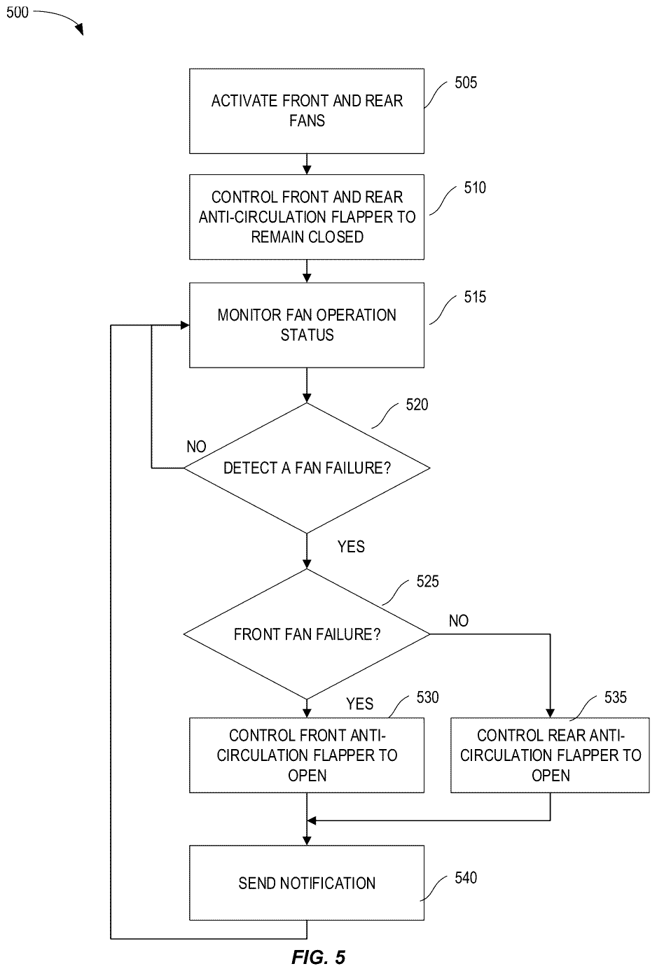

FIG. 5 depicts an example method 500 for managing airflow in a push-pull cooling system with anti-recirculation features, according to some embodiments of the present disclosure.

The example method 500 may be performed by a control unit, such as a CPU, microcontroller, programmable logic controller (PLC), or any other computing device capable of controlling an airflow cooling system. The airflow cooling system may include two redundant fan pods (e.g., 305 and 315 of FIG. 3A), one installed at the front (e.g., 305 of FIG. 3A) and the other at the rear of the chassis (e.g., 315 of FIG. 3A), with electronic components (e.g., 310 of FIG. 3A) positioned between the two pods. Each fan pod includes a fan (e.g., 320 or 330 of FIG. 3A) and an anti-recirculation flapper (e.g., 325 or 335 of FIG. 3A) that directs airflow. The front fan (e.g., 320 of FIG. 3B) draws cooler air from the outside into the chassis, where the air passes through the electronic components (e.g., 310 of FIG. 3A) and absorbs heat. The rear fan (e.g., 330 of FIG. 3B) then expels the heated air from the chassis. The control unit may be connected to both the fans and anti-recirculation flappers within the cooling system, monitoring the operational status of the fans and dynamically adjusting the flapper to maintain airflow.

At block 505, the control unit activates both the front and rear fans (e.g., 320 and 330 of FIG. 3A) to initiate airflow through the chassis. During normal fan operation, at block 510, the control unit keeps the flappers (e.g., 325 and 335 of FIG. 3A) closed in both fan pods. This prevents backflow and maintains airflow in a single direction, from the front to the rear, to maximize (or at least improve) cooling performance.

At block 515, the control unit monitors the performance of both fans and checks for any irregularities or signs of failure.

At block 520, the control unit checks if any fan has failed. If no failure is detected, the method 500 returns to block 515, where the control unit continues to monitor the fans. If a failure is detected, the method 500 proceeds to block 525.

At block 525, if the control unit detects that the front fan (e.g., 320 of FIG. 3C) has failed, the method 500 proceeds to block 530, where the control unit opens the front anti-recirculation flapper (e.g., 325 of FIG. 3C). This allows air to bypass the stationary front fan, maintaining cooling efficiency without significant airflow reduction.

If the front fan is functional but the rear fan (e.g., 330 of FIG. 3E) has failed, the method 500 proceeds to block 535, where the control unit opens the rear anti-recirculation flapper (e.g., 335 of FIG. 3E), allowing the warm air to be expelled through the outlet, bypassing the failed rear fan.

In some embodiments, the opening and closing of the anti-recirculation flappers may occur naturally due to air pressure differences between the inside and outside of the chassis or through passive control mechanisms (e.g., spring pressure), without the need for active intervention from the control unit. However, the control unit may still monitor the operational status of the flappers and step in if the flappers do not behave as expected. For example, if the natural pressure or spring pressure is insufficient, such that the flapper does not open or close as required to accommodate a fan failure, the control unit may actively adjust the flapper's position to maintain proper airflow.

In some embodiments, the front fan and rear fan pod (e.g., 305 and 310 of FIG. 3A) may each include more than one fan. These fans may be arranged side by side or in a stacked configuration within the pod, allowing for increased airflow capability and redundancy. The anti-recirculation flapper is located below the fans in each pod. When the flapper opens, it creates an alternative pathway for the air to bypass the non-functional fan and maintain airflow. For example, when the control unit detects that any of the fans in the front fan pod have failed, the control unit opens the front flapper, allowing air to bypass the stationary fan. If any fan in the rear fan pod fails, the rear flapper opens to maintain airflow and exhaust heated air out of the chassis.

At block 540, the control unit sends a notification to alert maintenance personnel that a fan (or a flapper) needs replacement. The method 500 then returns to block 515, where the control unit continues to monitor the cooling system.

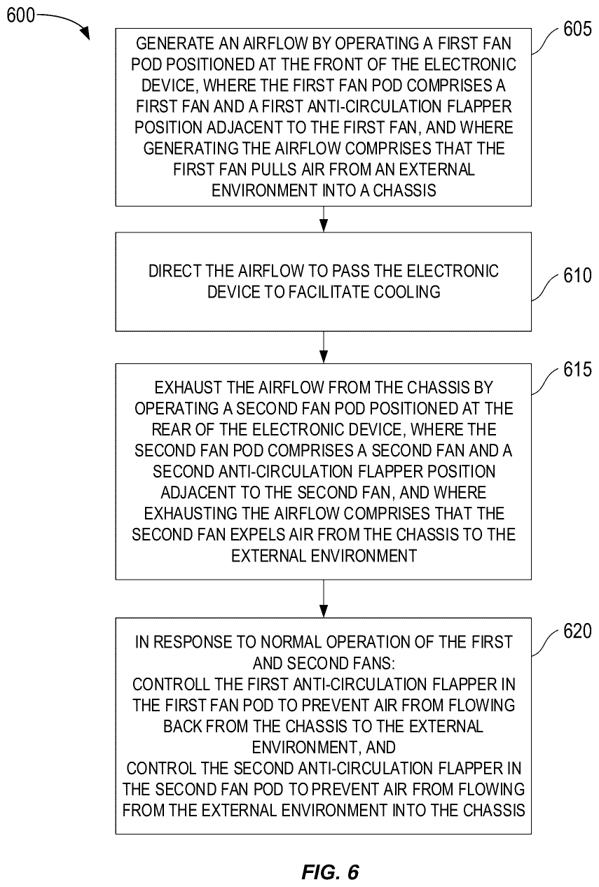

FIG. 6 is a flow diagram depicting an example method 600 for facilitating cooling of an electronic device within a chassis, according to some embodiments of the present disclosure.

At block 605, an airflow is generated by operating a first fan pod (e.g., 305 of FIG. 3A) positioned at the front of the electronic device (e.g., 310 of FIG. 3A). The first fan pod comprises a first fan (e.g., 320 of FIG. 3A) and a first anti-recirculation flapper (e.g., 325 of FIG. 3A) position below the first fan. The step of generating the airflow comprises that the first fan pulls air from an external environment into a chassis.

At block 610, the airflow is directed to pass the electronic device to facilitate cooling.

At block 615, the airflow is exhausted from the chassis by operating a second fan pod (e.g., 315 of FIG. 3A) positioned at the rear of the electronic device. The second fan pod comprises a second fan (e.g., 330 of FIG. 3A) and a second anti-recirculation flapper (e.g., 335 of FIG. 3A) position adjacent to the second fan. The step of exhausting the airflow comprises the second fan expels air from the chassis to the external environment.

At block 620, in response to normal operation of the first and second fans, the first anti-recirculation flapper in the first fan pod is controlled to prevent air from flowing back from the chassis to the external environment, and the second anti-recirculation flapper in the second fan pod is controlled to prevent air from flowing from the external environment into the chassis.

In some embodiments, a failure of the first fan in the first fan pod is detected, and in response to the detection, the first anti-recirculation flapper is controlled to pivot to an opening position to allow air to flow into the chassis through the first fan pod despite the failure of the first fan.

In some embodiments, a failure of the second fan in the second fan pod is detected, and in response to the detection, the second anti-recirculation flapper is controlled to pivot to an open position to allow air to be exhausted from the chassis through the second fan pod despite the failure of the second fan.

In some embodiments, in response to detecting a failure of the first fan in the first fan pod, the first fan pod is removed from the chassis, the failed first fan is replaced with a new fan, and the first fan pod is placed into the chassis.

In some embodiments, in response to detecting a failure of the second fan in the second fan pod, the second fan pod is removed from the chassis, the failed second fan is replaced with a new fan, and the second fan pod is placed into the chassis.

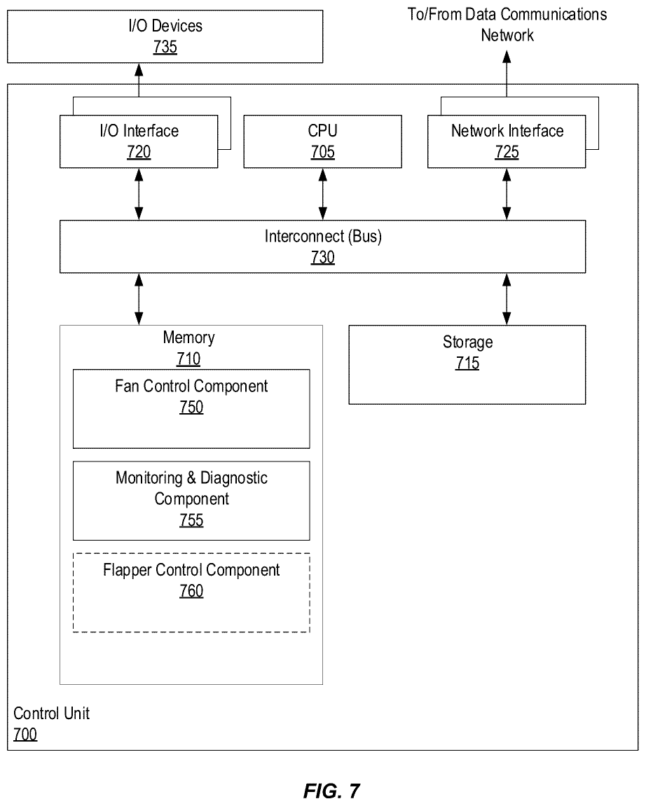

FIG. 7 depicts an example control unit 700 configured to perform various aspects of the present disclosure, according to some embodiments of the present disclosure. In some embodiments, the control unit may correspond to any computing device or virtual system capable of managing and controlling fans and anti-recirculation flappers within the cooling system.

As illustrated, the control unit 700 includes a CPU 705, memory 710, storage 715, one or more network interfaces 725, and one or more I/O interfaces 720. In the illustrated embodiment, the CPU 705 retrieves and executes programming instructions stored in memory 710, as well as stores and retrieves application data residing in storage 715. The CPU 705 is generally representative of a single CPU and/or GPU, multiple CPUs and/or GPUs, a single CPU and/or GPU having multiple processing cores, and the like. The memory 710 is generally considered to be representative of a random access memory. Storage 715 may be any combination of disk drives, flash-based storage devices, and the like, and may include fixed and/or removable storage devices, such as fixed disk drives, removable memory cards, caches, optical storage, network attached storage (NAS), or storage area networks (SAN).

In some embodiments, I/O devices 735 may include the fans and anti-recirculation flappers, and be connected to the control unit 700 via the I/O interface(s) 920. Further, via the network interface 725, the control unit 700 may be communicatively coupled with one or more other devices and components (e.g., via a network, which may include the Internet, local network(s), and the like). As illustrated, the CPU 705, memory 710, storage 715, network interface(s) 725, and I/O interface(s) 720 are communicatively coupled by one or more buses 930.

In the illustrated embodiment, the memory 710 includes a fan control component 750, a monitoring & diagnostic component 755, and a flapper control component 760. Although depicted as discrete components for conceptual clarity, in some embodiments, the operations of the depicted components (and others not illustrated) may be combined or distributed across any number of components. Further, although depicted as software residing in memory 710, in some embodiments, the operations of the depicted components (and others not illustrated) may be implemented using hardware, software, or a combination of hardware and software.

The fan control component 750 is configured to activate and manage the operations of the fans within the cooling system. In some embodiments, the fan control component 750 may control fan speed and start or stop the fans based on system requirements. In some embodiments, the fan control component 750 may adjust fan speed to optimize airflow based on temperature or other sensor data.

The monitoring & diagnostic component 755 is configured to monitor the status of the fans and flappers. In some embodiments, the monitoring & diagnostic component 755 may check operational data of the fans to detect failure. In some embodiments, the monitoring & diagnostic component 755 may monitor the status of the anti-recirculation flappers (whether open or closed). The component 755 may report the flapper status to the flapper control component 760 for active management. If any component, including a fan or flapper, is not functioning as expected, the monitoring & diagnostic component may trigger an alert and initiate corrective actions.

The flapper control component 760 is configured to manage the opening and closing of anti-recirculation flappers based on the operational status of the fans. When the monitoring & diagnostic component 755 detects a fan failure or reports the flapper status, the flapper control component 760 may open or close the corresponding flapper to maintain airflow, bypassing the non-functional fan. In some embodiments, the flapper control component 760 may be omitted if the flapper operate purely based on pressure difference.

In the illustrated example, the storage 715 may include a variety of data for effective operation of the control unit. The data may include, but is not limited to, system configurations (e.g., predefined settings for fan operation speeds, temperature threshold), diagnostic logs, fan or flapper failure records, and operational parameters.

While the foregoing is directed to embodiments of the present disclosure, other and further embodiments of the disclosure may be devised without departing from the basic scope thereof, and the scope thereof is determined by the claims that follow.

What is claimed is:

1. An apparatus for cooling an electronic device, comprising:
a first fan pod, comprising:
a first fan configured to pull air from an external environment into a chassis, and
a first anti-recirculation flapper positioned adjacent to the first fan within the first fan pod;
a second fan pod, comprising:
a second fan configured to exhaust air within the chassis to the external environment, and
a second anti-recirculation flapper positioned adjacent to the second fan within the second fan pod; and
the electronic device positioned between the first fan pod and the second fan pod, wherein airflow generated by the first fan pod passes the electronic device before being exhausted by the second fan pod.

2. The apparatus of claim 1, wherein, in response to a failure of the first fan within the first fan pod, the airflow is directed from the first anti-recirculation flapper, passes the electronic device, and is exhausted from the chassis via the second fan.

3. The apparatus of claim 1, wherein, in response to a failure of the second fan within the second fan pod, the airflow is directed from the first fan, passes the electronic device, and is exhausted from the chassis via the second anti-recirculation flapper.

4. The apparatus of claim 1, wherein the first anti-recirculation flapper in the first fan pod comprises one or more hinged plates.

5. The apparatus of claim 4, wherein the one or more hinged plates remain closed in response to a normal operation of the first fan within the first fan pod, blocking airflow from the chassis back to the external environment.

6. The apparatus of claim 4, wherein the one or more hinged plates pivot to an open position to allow air to flow into the chassis in response to a failure of the first fan within the first fan pod.

7. The apparatus of claim 1, wherein the second anti-recirculation flapper in the second fan pod comprises one or more hinged plates.

8. The apparatus of claim 7, wherein the one or more hinged plates remain closed in response to a normal operation of the second fan within the second fan pod, blocking airflow from the external environment into the chassis.

9. The apparatus of claim 7, wherein the one or more hinged plates pivot to an open position to allow air to be exhausted from the chassis into the external environment in response to a failure of the second fan within the second fan pod.

10. The apparatus of claim 1, wherein the first fan pod is connected to a duct comprising a channel with an angle of 90 degrees, through which the air pulled from the external environment is directed to turn by 90 degrees before entering the first fan.

11. The apparatus of claim 1, wherein the second fan pod is connected to a duct comprising a channel with an angle of 90 degrees, through which the air exhausted from the chassis is directed to turn by 90 degrees before being expelled to the external environment.

12. The apparatus of claim 1, wherein the first fan pod and the second fan pod have the same internal architecture, each comprising a fan and an anti-recirculation flapper positioned adjacent to the fan.

13. An apparatus for cooling an electronic device, comprising:
a fan pod, comprising:
a fan configured to direct air between an external environment and a chassis, and
an anti-recirculation flapper positioned adjacent to the fan within the fan pod, the flapper being configured to control the direction of airflow generated by the fan; and
the electronic device within the chassis, wherein the airflow generated by the fan passes the electronic device to facilitate cooling.

14. The apparatus of claim 13, wherein, upon failure of the fan, the anti-recirculation flapper opens, allowing air to enter the chassis or be exhausted from the chassis without obstruction from the fan.

15. The apparatus of claim 13, wherein the fan pod is connected to a duct comprising a channel with an angle of 90 degrees, through which the air pulled from the external environment is directed to turn by 90 degrees before entering the fan.

16. The apparatus of claim 13, wherein the fan pod is connected to a duct comprising a channel with an angle of 90 degrees, through which the air exhausted from the chassis is directed to turn by 90 degrees before being expelled to the external environment.

17. A computer-implemented method for cooling an electronic device, comprising:
generating an airflow by operating a first fan pod positioned at the front of the electronic device, wherein the first fan pod comprises a first fan and a first anti-recirculation flapper position adjacent to the first fan, and wherein generating the airflow comprises that the first fan pulls air from an external environment into a chassis;
directing the airflow to pass the electronic device to facilitate cooling;
exhausting the airflow from the chassis by operating a second fan pod positioned at the rear of the electronic device, wherein the second fan pod comprises a second fan and a second anti-recirculation flapper position adjacent to the second fan, and wherein exhausting the airflow comprises that the second fan expels air from the chassis to the external environment; and
in response to normal operation of the first and second fans:
controlling the first anti-recirculation flapper in the first fan pod to prevent air from flowing back from the chassis to the external environment, and
controlling the second anti-recirculation flapper in the second fan pod to prevent air from flowing from the external environment into the chassis.

18. The computer-implemented method of claim 17, further comprising:
detecting a failure of the first fan in the first fan pod; and
in response to the detection, controlling the first anti-recirculation flapper to pivot to an open position to allow air to flow into the chassis through the first fan pod despite the failure of the first fan.

19. The computer-implemented method of claim 17, further comprising:
detecting a failure of the second fan in the second fan pod; and
in response to the detection, controlling the second anti-recirculation flapper to pivot to an open position to allow air to be exhausted from the chassis through the second fan pod despite the failure of the second fan.

20. The computer-implemented method of claim 17, further comprising:
in response to detecting a failure of the first fan in the first fan pod:
removing the first fan pod from the chassis,
replacing the failed first fan with a new fan, and
placing the first fan pod into the chassis.
